(19) United States
(12) Patent Application Publication
(10) Pub. No.: US 2006/0017171 A1
(43) Pub. Date: Jan. 26, 2006

(54) Formation method and structure of conductive bumps

(75) Inventor: Chao-Fu Weng, Tainan City (TW)

Correspondence Address: BIRCH STEWART KOLASCH & BIRCH, PO BOX 747, FALLS CHURCH, VA, 22040-0747, US

(73) Assignee: Advanced Semiconductor Engineering Inc.

(21) Appl. No.: 11/185,848

(22) Filed: Jul. 21, 2005

(30) Foreign Application Priority Data
Jul. 23, 2004 (TW) 093122195

(51) Int. Cl. H01L 23/48

(52) U.S. Cl. 257/766; 257/734

(57) ABSTRACT

A formation method and structure of conductive bump are provided. A conductive bump is formed on a wafer through an under bump metallurgy layer. A nickel-based wetting layer in the under bump metallurgy layer is applied on the conductive bump to prevent stannum in the conductive bump from diffusing downwards.

### BACKGROUND OF THE INVENTION

1. Field of the Invention

This invention relates to a formation method and structure of conductive bumps, and more particularly to a method and structure of conductive bumps with wetting layer of nickel-based post.

2. Description of the Prior Art

With the development of IC technology, the package of the IC is strictly required for the function of a product subjects to the technology of the package. The qualities of package devices are tightly related to the conductive bumps between IC and print circuit board.

For example, FIG. 1 is schematically cross-viewed diagram illustrating the structure of a solder bump in accordance with a prior art. Shown on FIG. 1, a silicon wafer 10 has sequentially a bonding pad 12, a passivation layer 14, a conductive layer 22 and a solder bump 24 thereon. The bonding pad 12, such as aluminum or copper pad, provides the silicon wafer 10 with a conductive surface for the electrical connection. Furthermore, the passivation layer 14 exposes the partial surface of the conductive bonding pad 12 and is configured for protecting and planarizing the surface of the silicon wafer 10. The conductive layer 22, such as an under bump metallurgy layer formed by electroplating, contacts and electrically connects the partial surface of the bonding pad 12. Generally, the conductive layer 22 consists of an adhesive layer 16, a barrier diffusion layer 18 and a wetting layer 20 for contacting a solder bump 24 with the bonding pad 12. The wetting layer 20 may have a stud structure intruding into the bulk body of the solder bump 24 for strengthening the vertical support to prevent the solder bump 24 from collapsing.

However, during the process of reflowing, stannum (Sn) in the solder bump 24 aforementioned may diffuse downwards to form inter-metallic compound (IMC) of copper-stannum alloy (Cu₃Sn) with the copper-based wetting layer 20. The formation of the inter-metallic compound can not hinder stannum (Sn) in the solder bump 24 from successively diffusing toward the wetting layer 20. Thus, the excessive consumption of stannum in the solder bump 24 causes the formation of the inter-metallic compound with an unwanted thickness. The thicker the inter-metallic compound is, the more possibly the fracture in thermal-fatigue test happens. Moreover, the excessive consumption of stannum in the solder bump 24 results in the poor connection between the solder bump 24 and a print circuit board during coming soldering and further poor quality of soldering. Furthermore, that copper stud successively reacts with the solder bump 24 may cause the copper stud failing in sustaining. Accordingly, it is important to prevent the formation of the inter-metallic compound to improve the quality of soldering.

### SUMMARY OF THE INVENTION

The method of the present invention addresses many of the shortcomings of the prior art. It is one of objects of the present invention to provide a method of forming conductive bumps to resolve the downward diffusion issue of stannum (Sn) for general conductive bumps. The use of a nickel-based post can prevent stannum in a solder bump from diffusing downward a wetting layer.

It is another object of the present invention to provide a formation method and structure of lead-free conductive bumps to resolve the formation of excessive inter-metallic compounds. A nickel post is used as a wetting layer for preventing the formation of the excessive inter-metallic compounds and the collapse of the lead-free conductive bumps.

In accordance with an exemplary embodiment of the present invention, formation method and structure of a conductive bump are provided. A conductive bonding pad is on a wafer. A passivation layer covers the wafer and exposes a portion of the conductive bonding pad. A conductive barrier layer contacts and is positioned on the exposed conductive bonding pad. A wetting layer of nickel-based post contacts and is positioned on the conductive barrier layer. A conductive bump contacts and is positioned on the wetting layer of nickel-based post.

### BRIEF DESCRIPTION OF DRAWINGS

The foregoing and other objects, features, and advantages of the invention will become more readily apparent upon reference to the following detailed description of a presently preferred embodiment, when taken in conjunction with the accompanying drawings in which like numbers refer to like parts, and in which:

FIG. 1 is a schematic cross-sectional diagram illustrating the formation of lead solder bump by deposition of thin film in accordance with a prior art;

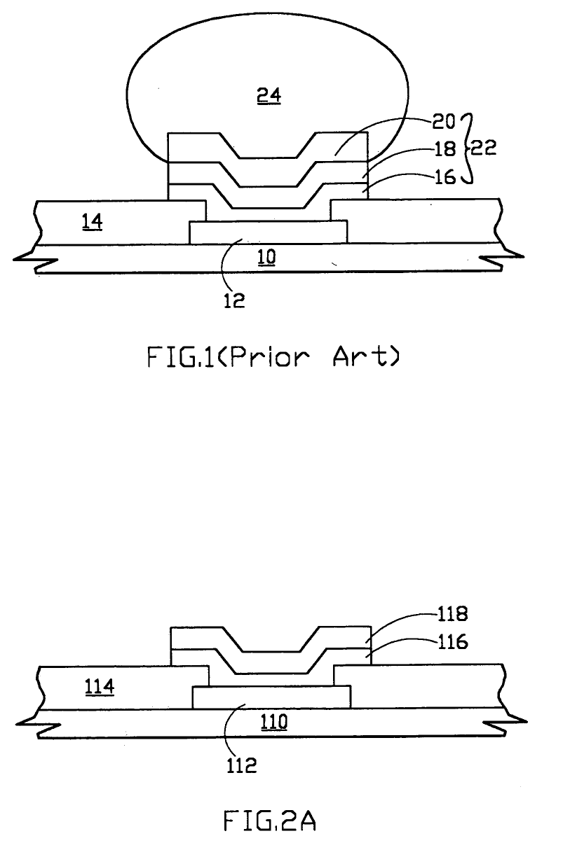

FIGS. 2A through 2C are schematic cross-sectional diagrams illustrating the method of forming conductive bumps in accordance with the present invention; and

FIG. 3 is a schematic cross-sectional diagram illustrating another embodiment in accordance with the present invention.

### DETAILED DESCRIPTION OF THE INVENTION

An appropriate and preferred embodiment will now be described in the formation of conductive bumps. It should be noted, however, that this embodiment is merely an example and can be variously modified without departing from the scope of the present invention.

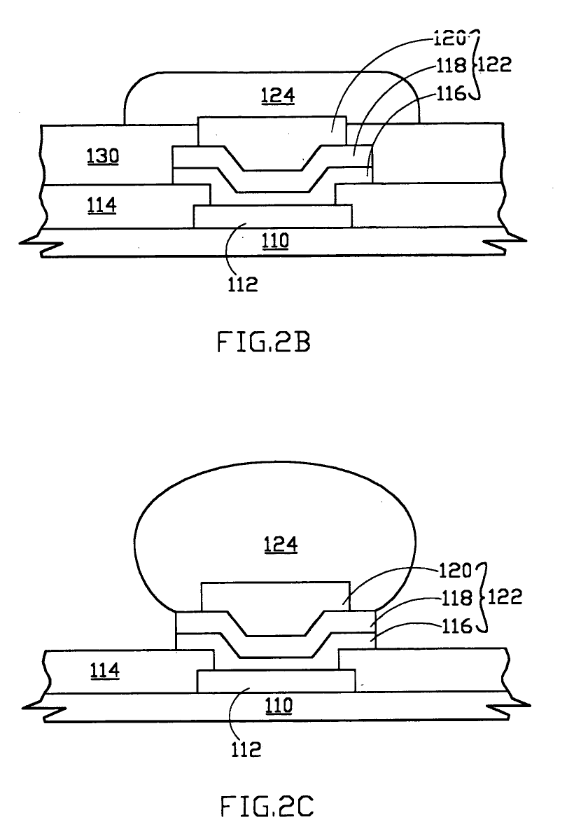

FIGS. 2A-2C are schematic cross-sectional diagrams illustrating the manufacture of conductive bumps in accordance with one embodiment of the present invention. Depicted on FIG. 2A, a wafer 110 has one or more conductive bonding pads 112, a passivation layer 114, an adhesive layer 116 and a barrier diffusion layer 118 thereon. In one embodiment, the wafer 110, such as a silicon wafer, may have other semiconductor devices on an active surface. On the other hand, the active surface of the wafer 110 contacts the conductive bonding pad 112 and the passivation layer 14. The conductive bonding pads 112 on the active surface, such as aluminum or copper pads, are formed by any suitable methods and configured for the electrical connection with other exterior circuits. Furthermore, the passivation layer 114 made of oxide, nitride or other organic materials covers the active surface and the parts of the conductive bonding pad 112 for the purposes of protecting and planarizing the active surface. It is noted that the passivation layer 114 also exposes the partial surface of the conductive bonding pad 112.

Next, by any suitable methods, such as executing evaporation or sputtering after photolithography and etching, an adhesive layer 116 and a barrier diffusion layer 118 are sequentially formed on the conductive bonding pads 112, in which the adhesive layer 116 is positioned on and contacts the exposed the conductive bonding pad 112 and the parts of the passivation layer 114. In the embodiment, the adhesive layer 116 is a layer or layers of titanium, chromium, nickel-chromium alloy, aluminum or tantalum-based metal, but not limited aforementioned. Furthermore, the barrier diffusion layer 118 is a layer or layers of platinum, palladium, nickel, rhodium, wolfram or molybdenum-based metal, but not limited aforementioned. Alternatively, a conductive barrier layer for replacing both the adhesive layer 116 and the barrier diffusion layer 118 is applied on the conductive bonding pad 112, in which the conductive barrier layer is a layer or layers of tantalum/tantalum nitride. It is understandable that such a conductive barrier layer is a complex layer of plating capable of adhesion and barrier diffusion.

Next, depicted in FIG. 2B, a mask layer 130, such as a dry film or a photoresist liquid layer, is applied on the barrier diffusion layer 118 and the passivation layer 114. With photolithographical patterning and etching, the part of the mask layer 130 above the barrier diffusion layer 118 is removed to expose the partial surface of the barrier diffusion layer 118. Next, one of the features of the present invention, a nickel-based wetting layer 120 is formed on the barrier diffusion layer 118 and contacts the exposed barrier diffusion layer 118. The nickel-based wetting layer 120, the barrier diffusion layer 118 and the adhesive layer 116 constitute an under bump metallurgy layer 122. In the embodiment, the electroplating or sputtering method is applied to the formation of the nickel-based wetting layer 120, as so to provide it with the thicker thickness. On the other hand, the sidewall of the nickel-based wetting layer 120 recesses onto the barrier diffusion layer 118 and the adhesive layer 116. Accordingly, the nickel-based wetting layer 120 advantageously increases wettable area and strengthens a coming conductive bump with the intrusive post structure thereinto. Thus, the nickel-based wetting layer 120 advantageously prevents the coming conductive bump from collapsing and the conductive bonding pad 112 from damage. In the embodiment, the nickel-based wetting layer 120 is a layer or layers of nickel metal or nickel alloy.

Next, the conductive bump 124 is formed by screen printing or electroplating. Shown in FIG. 2C, the mask layer 130 is removed and reflowing is then applied to the conductive bump 124. In the embodiment, a nickel-stannum alloy (NiₓSn) generates between the interface of the conductive bump 124, such as a lead-free bump, and the nickel-based wetting layer 120. The formation of nickel-stannum alloy, such as Ni₃Sn, wholly prevents the formation of traditional copper-stannum alloy (CuₓSn) so that the reliability of a product is improved. Moreover, the nickel-stannum alloy also hinders the interface between the conductive bump 124 and the nickel-based wetting layer 120 from the successive diffusion of elements contributive to unwanted alloy reaction. Thus, the consumption of the interface between the conductive bump 124 and the nickel-based wetting layer 120 can be reduced to prevent poor soldering and weak support provided by the under bump metallurgy layer.

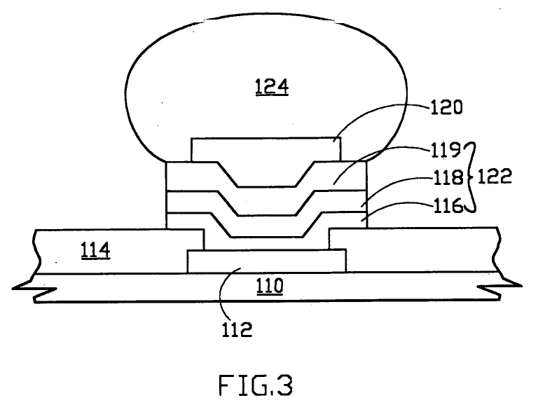

FIG. 3 is a schematic cross-sectional diagram illustrating a conductive bump in accordance with another embodiment of the present invention. The disclosed structure different from the one in FIG. 2C is to have a wetting layer 119 that is constituted the under bump metallurgy layer 122 with the adhesive layer 116 and the barrier diffusion layer 118. In the embodiment, electroplating or sputtering method is applied to the formation of the wetting layer 119. The wetting layer 119 is a layer or layers of nickel metal or nickel alloy.

Accordingly, structure and formation method of conductive bump are provided. A conductive bonding pad is formed on a wafer. A passivation layer covers the wafer and exposes a portion of the conductive bonding pad. An under bump metallurgy layer contacts and is positioned on the exposed conductive bonding pad. A layer of post nickel metal contacts and is positioned on the under bump metallurgy layer. A conductive bump contacts and is positioned on the under bump metallurgy and further embeds the layer of post nickel metal.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A structure of a conductive bump, comprising:
a conductive bonding pad on a wafer;
a passivation layer covering said wafer and exposing a portion of said conductive bonding pad;
a conductive barrier layer contacting and positioning on said exposed conductive bonding pad;
a nickel-based wetting layer contacting and positioning on said conductive barrier layer; and
a conductive bump contacting and positioning on said nickel-based wetting layer.

2. The structure of the conductive bump according to claim 1, wherein said conductive barrier layer comprises:
an adhesive layer contacting and positioning on said exposed conductive bonding pad; and
a barrier diffusion layer contacting and positioning on said adhesive layer.

3. The structure of the conductive bump according to claim 2, wherein said adhesive layer is selected from the group consisting of titanium, chromium, nickel/chromium alloy, aluminum and tantalum.

4. The structure of the conductive bump according to claim 2, wherein said barrier diffusion layer is selected from the group consisting of platinum, palladium, nickel, rhodium, wolfram and molybdenum.

5. The structure of the conductive bump according to claim 1, wherein said conductive bonding pad comprises of aluminum or copper metal.

6. The structure of the conductive bump according to claim 1, wherein said wafer is a silicon wafer.

7. The structure of the conductive bump according to claim 1, wherein said passivation layer is selected from the group consisting of oxide, nitride and organic material.

8. The structure of the conductive bump according to claim 1, wherein said conductive barrier layer is made of tantalum/tantalum nitride.

9. The structure of the conductive bump according to claim 1, wherein said nickel-based wetting layer has a post structure intruding into said conductive bump.

10. The structure of the conductive bump according to claim 1, wherein said nickel-based wetting layer has a sidewall recessed into said conductive barrier layer.

11. The structure of the conductive bump according to claim 1, wherein said nickel-based wetting layer is made of nickel metal.

12. The structure of the conductive bump according to claim 1, wherein said nickel-based wetting layer is made of nickel alloy.

13. The structure of the conductive bump according to claim 1, wherein said conductive bump is a lead-free solder bump.
